(19) United States
(12) Patent Application Publication
(10) Pub. No.: US 2013/0313625 A1
(43) Pub. Date: Nov. 28, 2013

(54) SEMICONDUCTOR DEVICE AND METHOD OF FABRICATING THE SAME

(71) Applicant: Ching-Hung Kao, Hsinchu County (TW)

(72) Inventor: Ching-Hung Kao, Hsinchu County (TW)

(21) Appl. No.: 13/481,946

(22) Filed: May 28, 2012

(51) Int. Cl. H01L 29/788; H01L 21/283

(52) U.S. Cl. 257/319; 438/594; 257/E29.3; 257/E21.209

(57) ABSTRACT

A semiconductor device includes a semiconductor substrate and at least a first gate structure disposed on the semiconductor substrate. Furthermore, a spacer only disposed at a side of the first gate structure, and a material of the spacer does not comprise nitride.

### BACKGROUND OF THE INVENTION

1. Field of the Invention

The present invention relates to a semiconductor device and a method of fabricating the same, and more particularly to a semiconductor device without nitride residue and a method of fabricating the same.

2. Description of the Prior Art

A flash memory is a non-volatile memory, which can preserve data within the memory even when an external power supply is off. Recently, because flash memories are electrically re-writable and electrically re-erasable, they have been widely applied in the fabrication of electrical products, such as mobile phones, digital cameras, video players, personal digital assistants (PDA) or systems on a chip (SOC).

To meet the requirements of low power consumption, fast response, low cost and high integration rate of electronic products, integrating processes of different semiconductor devices having various electrical performances and functions is the trend of current semiconductor processes. For example, flash memory cells in the flash memory array area and metal-oxide-semiconductor transistors (MOS) in the logic circuit area may be formed in the same chip. As the requirements of process conditions are the same, a semiconductor process could be performed to manufacture different semiconductor devices at the same time in order to save costs, however, when the requirements of process conditions are incompatible, performing a semiconductor process of a semiconductor device may deteriorate the performances of the other semiconductor device. For example, when the etching process is performed to remove a part of the nitride layer to form the spacer of the MOS, the nitride layer close to flash memory cell may not be totally removed due to the step height, and some nitride residue from the remaining nitride layer may be formed on the sidewalls of the floating gate. The nitride residue may attract or reject electric charges, accordingly, the residue may influence the capability of storing hot electrons of the floating gate, and in other words, the nitride residue may affect the performances such as the data retention ability of the flash memory cell.

Consequently, how to avoid the formation of nitride residue to improve the performances of the flash memory cell is still an important issue in the field.

### SUMMARY OF THE INVENTION

An objective of the present invention is therefore to provide a semiconductor device and a method of fabricating the same in order to avoid the formation of residue caused by other semiconductor processes.

According to one exemplary embodiment of the present invention, a semiconductor device is provided. The semiconductor device includes a semiconductor substrate and at least a first gate structure disposed on the semiconductor substrate. Furthermore, a spacer only disposed at a side of the first gate structure, and a material of the spacer does not include nitride.

According to another exemplary embodiment of the present invention, a method of fabricating a semiconductor device includes the following steps. At first, a gate stack layer is formed on a semiconductor substrate, and the gate stack layer includes at least an opening. Then, a protective layer is formed for filling the opening. Subsequently, a part of the gate stack layer is removed to form two gate structures, and the protective layer is between the two gate structures.

The present invention provides a semiconductor device having a spacer only disposed at a side of the gate structure and a protective layer disposed at another side of the gate structure, the remaining residues caused by other semiconductor processes are then prevented to form on the sidewalls of the gate structure, consequently, the data retention ability of the flash memory cell may be preserved, and the performance of the semiconductor device can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a semiconductor device according to a preferred exemplary embodiment of the present invention.

FIG. 2 through FIG. 10 are schematic diagrams illustrating a method of fabricating a semiconductor device according to a preferred exemplary embodiment of the present invention.

### DETAILED DESCRIPTION

To provide a better understanding of the present invention, preferred exemplary embodiments will be described in detail. The preferred exemplary embodiments of the present invention are illustrated in the accompanying drawings with numbered elements.

Please refer to FIG. 1, which is a schematic diagram illustrating a semiconductor device according to a preferred exemplary embodiment of the present invention. As shown in FIG. 1, the semiconductor device 10 includes at least a first gate structure 14 and at least a second gate structure 16 disposed on a semiconductor substrate 12. The semiconductor substrate 12 includes a substrate composed of Si, AsGa, silicon on insulator (SOI) layer, epitaxial layer, SiGe layer or other semiconductor materials.

The semiconductor device 10 can be chosen to be a flash memory cell for example. The first gate structure 14 and the second gate structure 16 respectively includes a first dielectric layer 18, a first gate 20, a second dielectric layer 22 and a second gate 24 disposed sequentially on the semiconductor substrate 12. The first dielectric layer 18 and the second dielectric layer 22 may be made of dielectric material such as silicon oxide, silicon oxynitride, or other high-k dielectric layers with a dielectric constant larger than 4. The first gate 20 and the second gate 24 may be made of conductive materials such as polysilicon, metal silicide or metal layer with specific work function.

In this exemplary embodiment, the first dielectric layer 18 made of silicon oxide may serve as a tunneling oxide layer, and the hot electrons could get in/out of the first gate 20, thereby achieving data accessing. The first gate 20 made of polysilicon may serve as a floating gate used to store hot electrons. The second dielectric layer 22 as a multi-layered structure such as oxide-nitride-oxide (ONO) stacked layer may serve as an inter-gate dielectric layer used to electrically insulate the first gate 20 from the second gate 24. The second gate 24 made of polysilicon may serve as a control gate used for controlling the data accessing function of the semiconductor device 10. Furthermore, the first gate structure 14 and the second gate structure 16 have substantially the same height, but not limited thereto.

It is appreciated that, a spacer 26A/26B is only disposed at a side of the first gate structure 14/the second gate structure 16, i.e. the spacer 26A and the spacer 26B are respectively disposed at the opposite sidewalls outer sides of the first gate structure 14 and the second gate structure 16, and a material of the spacer 26A/26B does not include nitride. In this exemplary embodiment, the spacer 26A/26B made of conductive material such as polysilicon, metal silicide or a metal layer with a specific work function may serve as a select gate used to assist the control of the data accessing function of the semiconductor device 10. In other exemplary embodiments, the spacer 26A/26B may be made of dielectric material, and the dielectric material does not include nitride, in order to be used in other kinds of semiconductor processes. Additionally, in order to electrically insulate the first gate 20, the second gate 24 and the spacer 26A/26B from each other, a dielectric layer 28 is disposed between the spacer 26A/26B and the first gate 20, the second gate 24 and the semiconductor substrate 12. In this exemplary embodiment, the dielectric layer 28 covers the top of the first gate structure 14 and the top of the second gate structure 16, i.e. the top of the second gate 24.

Please refer to FIG. 1 again, a protective layer 30 is disposed at another side S1 of the first gate structure 14 with respect to the spacer 26A and at another side S2 of the second gate structure 16 with respect to the spacer 26B, i.e. the protective layer 30 is disposed on the semiconductor substrate 12 between the first gate structure 14 and the second gate structure 16. The protective layer 30 is made of dielectric material such as silicon oxide and a material of the protective layer 30 does not include nitride. It is appreciated that, in this exemplary embodiment, a height of the protective layer 30 is substantially the same as a height of the first gate structure 14, and the opening between the first gate structure 14 and the second gate structure 16 could be filled up with the protective layer 30, in order to prevent unfavorable residues from being formed in the opening between the first gate structure 14 and the second gate structure 16. Additionally, the protective layer 30 and the spacer 26A/26B are disposed at two sides of the first gate structure 14/the second gate structure 16 to avoid the formation of residues including nitride at the sidewalls of the first gate structure 14/the second gate structure 16, so that the functions of the first gate 20, such as storage of hot electrons, will not be affected, and the performances of the semiconductor device 10 can be stabilized.

Moreover, in this exemplary embodiment, the protective layer 30 is disposed under the dielectric layer 28 between the first gate structure 14 and the second gate structure 16, and another U-shaped dielectric layer 32 is disposed between the protective layer 30 and the first gate 20, the second gate 24 and the semiconductor substrate 12. In other words, the dielectric layer 28 covers the protective layer 30 and the U-shaped dielectric layer 32, and the protective layer 30 could be surrounded by the dielectric layer 28 and the U-shaped dielectric layer 32. The protective layer 30, the dielectric layer 28 and the U-shaped dielectric layer 32 are made of dielectric material, like silicon oxide formed through a thermal oxidation process or a deposition process for example. More specifically, the dielectric layer 28 and the protective layer 30 are silicon oxide layers formed through different deposition processes, and the U-shaped dielectric layer 32 is a silicon oxide layer formed through thermal oxidation process, i.e. the U-shaped dielectric layer 32, the protective layer 30 and the dielectric layer 28 are formed sequentially. Furthermore, the source/drain regions 34/36/38 are respectively formed in the semiconductor substrate 12 at two sides of each of the first gate structure 14 and the second gate structure 16. In this exemplary embodiment, the source/drain region 36 disposed in the semiconductor substrate 12 underneath the protective layer 30, wherein the source/drain region 36 is overlapped by the protective layer 30, may serve as a communal doped region for the first gate structure 14 and the second gate structure 16, which may reduce the occupied area of the semiconductor device 10, thereby increasing the utilization rate of the semiconductor substrate 12.

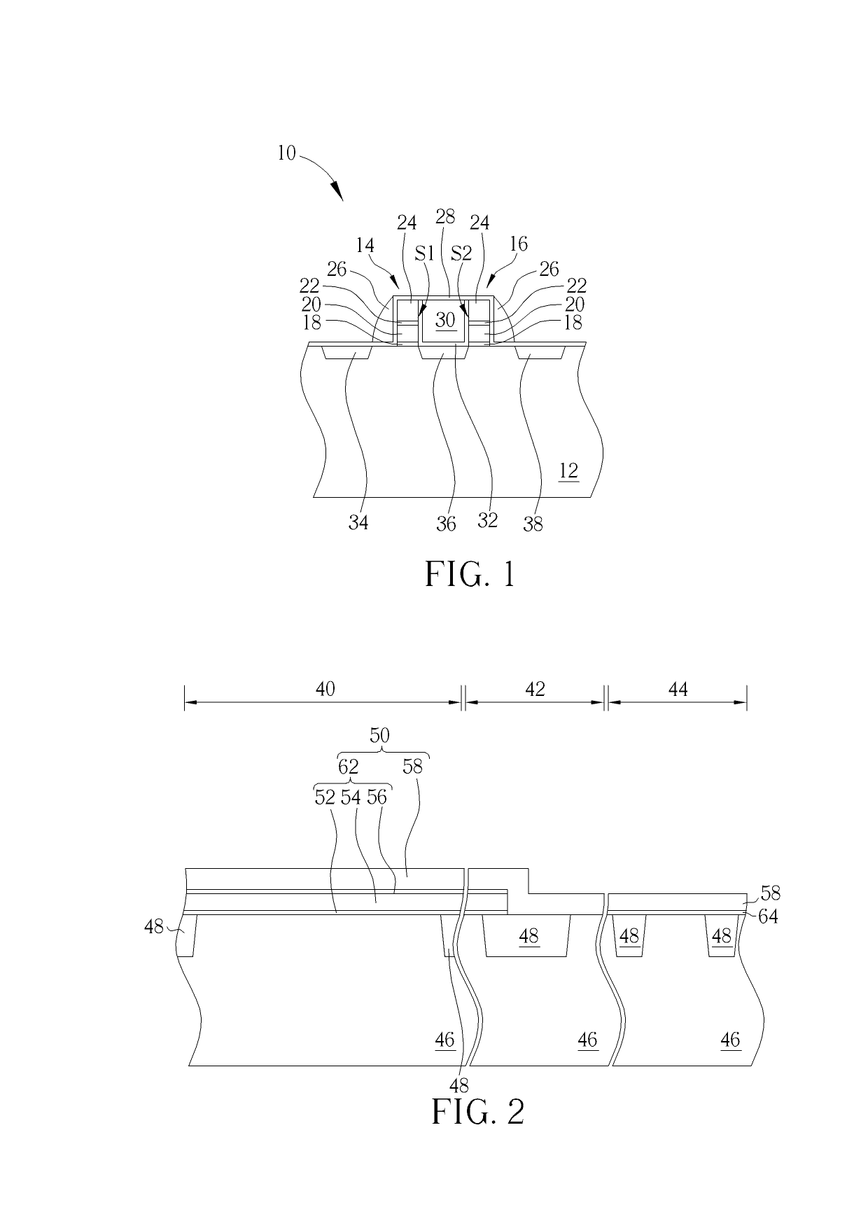

The present invention also provides a method for fabricating a semiconductor device. Please refer to FIGS. 2 through 10, which are schematic diagrams illustrating a method of fabricating a semiconductor device according to a preferred exemplary embodiment of the present invention. As shown in FIG. 2, at first, a semiconductor substrate 46 having a first region 40, a second region 42 and a third region 44 defined thereon is provided. The semiconductor substrate 46 includes a substrate composed of Si, AsGa, silicon on insulator (SOI) layer, epitaxial layer, SiGe layer or other semiconductor materials. The semiconductor device of the present invention is predetermined to be formed in the first region 40, and other semiconductor devices, such as a p-type metal-oxide-semiconductor transistor (PMOS), an n-type metal-oxide-semiconductor transistor (NMOS), or a metal-oxide-semiconductor transistor having a strained silicon structure (strained-Si MOS) may be predetermined to be formed in the third region 44, but not limited thereto. Furthermore, the second region 42 is a periphery region between the first region 40 and the third region 44. Additionally, the semiconductor substrate 46 further includes a plurality of shallow trench isolations (STIs) 48 respectively disposed in the first region 40, the second region 42 and the third region 44 for electrical insulation. The STIs 48 are usually made of dielectric material such as silicon oxide, as the STI processes are known to those skilled in the art, the details are omitted herein for brevity. The locations and the order of formation of STIs are not limited.

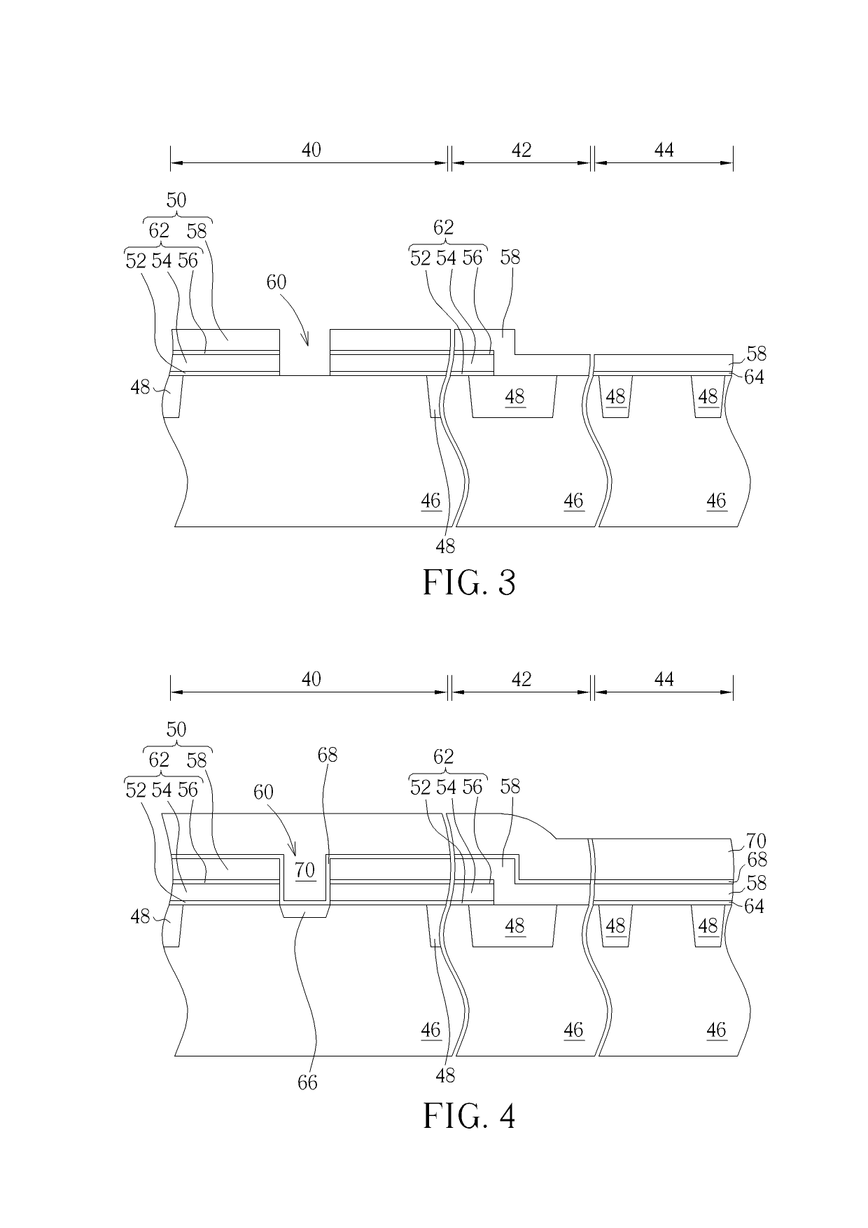

Please refer to FIG. 2 and FIG. 3 together. As shown in FIG. 2 and FIG. 3, a gate stack layer 50 is formed on the semiconductor substrate 46. The gate stack layer 50 includes a first dielectric layer 52, a first gate layer 54, a second dielectric layer 56 and a second gate layer 58 disposed sequentially on the semiconductor substrate 46, and the gate stack layer 50 includes at least an opening 60. The method of forming the gate stack layer 50 includes the following steps. At first, a first dielectric material layer (not shown), a conductive material layer (not shown) and a second dielectric material layer (not shown) are sequentially formed on the semiconductor substrate 46. Then, a patterned photoresist layer (not shown) or a patterned cap layer (not shown) is formed on the second dielectric material layer through a photolithography process. Subsequently, the patterned photoresist layer or the patterned cap layer is used as a mask, and an anisotropic etching process, such as reactive-ion-etching (RIE) process, is performed to remove a part of the second dielectric material layer, a part of the conductive material layer, and a part of the first dielectric material layer. Therefore, a patterned stack layer 62 is formed on the semiconductor substrate 46 in the first region 40 and the second region 42. The patterned stack layer 62 includes the first dielectric layer 52, the first gate layer 54 and the second dielectric layer 56. Afterwards, the patterned photoresist layer or the patterned cap layer is removed.

Subsequently, the second gate layer 58 is formed on the semiconductor substrate 46, and the second gate layer 58 covers the patterned stack layer 62 and the semiconductor substrate 46. Then, a part of the second gate layer 58 and a part of the patterned stack layer 62 in the first region 40 are removed to form the opening 60 in the gate stack layer 50. The method for forming the opening 60 includes performing a photolithography process and the following steps. Another patterned photoresist layer (not shown) or a patterned cap layer (not shown) is formed on the second gate layer 58. Then, the patterned photoresist layer or the patterned cap layer is used as a mask, and an anisotropic etching process is performed to remove a part of the second gate layer 58, a part of the second dielectric layer 56, a part of the first gate layer 54 and a part of the first dielectric layer 52. Therefore, at least an opening 60 is formed in the gate stack layer 50. Finally, the patterned photoresist layer or the patterned cap layer is removed.

In this exemplary embodiment, the first dielectric layer 52 is made of dielectric material such as silicon oxide, silicon oxynitride, or other high-k gate dielectric layers with a dielectric constant larger than 4 formed through a thermal oxidation process or a deposition process such as a chemical vapor deposition (CVD) process or an atomic layer deposition (ALD) process. The second dielectric layer 56 includes a single layered structure or a multi-layered structure made of dielectric material, like for example an oxide-nitride-oxide (ONO) stacked layer formed through a thermal oxidation process, a thermal nitridation process and a plasma-enhanced CVD (PECVD) process, or a low pressure chemical vapor deposition (LPCVD). The first gate layer 54 and the second gate layer 58 are made of conductive materials such as polysilicon, metal silicide or metal layer with specific work functions, for example, polysilicon formed through a deposition process such as LPCVD process or PECVD process, and polysilicon could be in-situ doped during the deposition process according to the process requirement. Furthermore, the first gate layer 54 and the second gate layer 58 could be made of different conductive materials.

In addition, to protect the semiconductor substrate 46 in the third region 44, a barrier layer (not shown) includes silicon oxide layer and nitride layer could be selectively formed thereon, or a part of the first dielectric layer 52 could be kept thereon to serve as a barrier layer. After the formation of the patterned stack layer 62 and before the formation of the second gate layer 58, the barrier layer could be removed, and a gate dielectric layer 64 made of silicon oxide is formed on the semiconductor substrate 46 in the third region 44 through a thermal oxidation process. A thickness of the gate dielectric layer 64 in the third region 44 could be different from a thickness of the first dielectric layer 52 in the first region 40.

As shown in FIG. 4, after the formation of the opening 60 in the first region 40, an ion implantation process is further performed to form a doped region 66 in the semiconductor substrate 46 exposed by the opening 60, and the doped region 66 could serve as a source/drain region of the later formed semiconductor device. Subsequently, a dielectric layer 68 is formed on the gate stack layer 50. In this exemplary embodiment, the exposed silicon substrate and polysilicon may be oxidized through a thermal oxidation process to form the dielectric layer 68 on the surface of the first gate layer 54, the second gate layer 58 and the semiconductor substrate 46, but not limited thereto. The dielectric layer 68 could also be made of other proper dielectric materials through deposition processes, and the material of the dielectric layer 68 preferably excludes nitride. The dielectric layer 68 covers the second gate layer 58 and the surfaces exposed by the opening 60, and directly contacts the semiconductor substrate 46. Furthermore, the opening 60 is not filled up with the dielectric layer 68. Then, a protective layer 70 filling the opening 60 is conformally formed on the semiconductor substrate 46. The originally formed protective layer 70 covers the dielectric layer 68 and overlaps the second gate layer 58 at two sides of the opening 60. The protective layer 70 is made of dielectric material and a material of the protective layer 70 does not include nitride. A chemical vapor deposition (CVD) process can be performed to form the protective layer 70 made of silicon oxide, but not limited thereto.

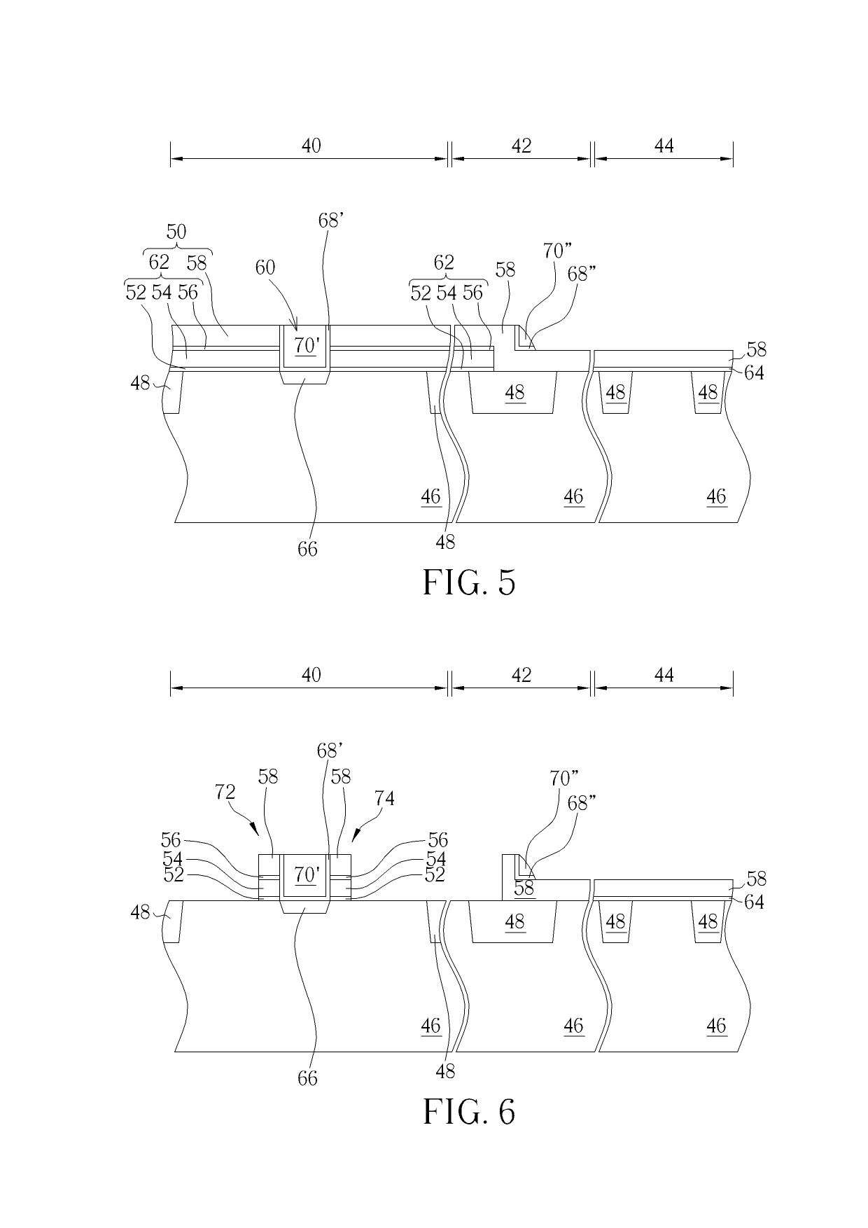

As shown in FIG. 5, an etching process is performed to remove a part of the dielectric layer 68 and a part of the protective layer 70 to fully expose the top of the second gate layer 58, and the etching process includes an anisotropic etching process. In the first region 40, the remaining protective layer 70′ could still fill the opening 60 but not overlap the second gate layer 58 at both sides of the opening 60. The protective layer 70′ preferably has a planar top, and its top may be coplanar with the top of the second gate layer 58. In addition, the remaining dielectric layer 68′ located between the gate stack layer 50 and the protective layer 70′ still covers the surfaces exposed by the opening 60 and has a U-shaped cross-section. In the second region 42, the previously formed patterned stack layer 62 is only disposed in a part of the second region 42, and a height of the top relative to the semiconductor substrate 46 of the second gate layer 58 on the patterned stack layer 62 is therefore substantially different from that of the second gate layer 58 not on the patterned stack layer 62, i.e. the second gate layer 58 has a non-planar top in the second region 42. Accordingly, after the etching process performed to remove a part of the dielectric layer 68 and a part of the protective layer 70 in the second region 42, the remaining dielectric layer 68″ having an L-shaped cross-section and the remaining protective layer 70″ having a spacer shape are formed on the corner of the second gate layer 58. Furthermore, as the second gate layer 58 in the third region 44 has a fixed height, the protective layer 70 and the dielectric layer 68 in the third region 44 can be totally removed to expose the top of the second gate layer 58.

As shown in FIG. 6, a mask (not shown), for example, a patterned photoresist layer is formed, and an etching process is performed to remove a part of the gate stack layer 50. In the first region 40, the remaining gate stack layer forms two gate structures 72/74, and the protective layer 70′ is between the two gate structures 72/74. A height of the protective layer 70′ is substantially the same as a height of each of the two gate structures 72/74. In the second region 42, the patterned stack layer 62 is totally removed, only a part of the second gate layer 58, the L-shaped dielectric layer 68″ and the spacer shaped protective layer 70″ are kept, but not limited thereto. Furthermore, the third region 44 is covered by the mask, so that the second gate layer 58 and the gate dielectric layer 64 are kept on the semiconductor substrate 46 in the third region 44 without being affected by the etching process.

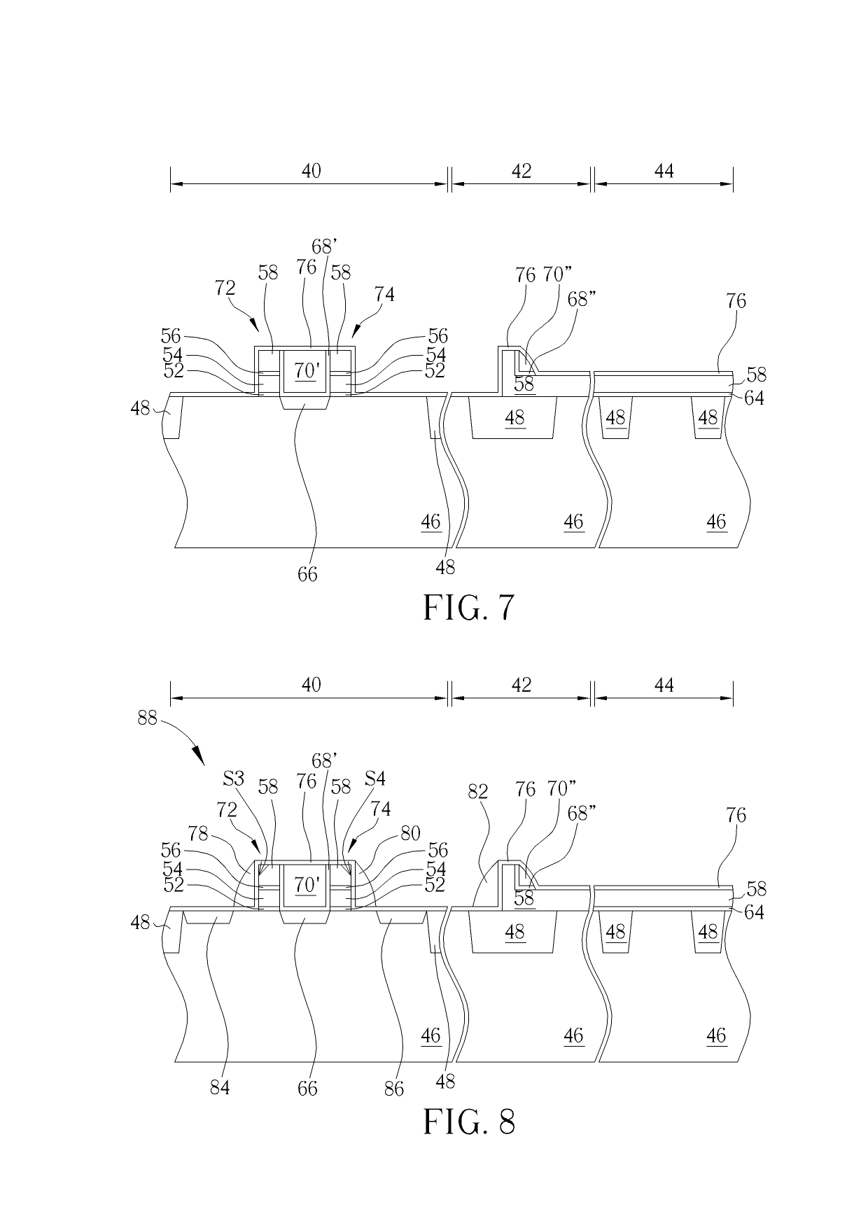

As shown in FIG. 7, another dielectric layer 76 is formed on the semiconductor substrate 46, and the dielectric layer 76 covers the two gate structures 72/74 and the protective layer 70′ in the first region 40, the second gate layer 58 in the second region 42, and the second gate layer 58 in the third region 44. The dielectric layer 76 could be silicon oxide layer formed through a chemical vapor deposition (CVD) process, but not limited thereto. In this exemplary embodiment, the dielectric layer 76 on the protective layer 70′, the protective layer 70′ and the U-shaped dielectric layer 68′ are all made of silicon oxide, however, they are formed through different processes, more specifically, the protective layer 70′ is formed after the formation of the U-shaped dielectric layer 68′, and before the formation of the dielectric layer 76.

Afterwards, as shown in FIG. 8, two spacers 78/80 are respectively formed at the opposite sidewall outer sides S3/S4 of the two gate structures 72/74. The method for forming the spacers 78/80 includes the following steps. At first, a material layer (not shown) is conformally formed on the dielectric layer 76 in the first region 40 and in the second region 42, and the material layer is made of conductive material such as polysilicon, metal silicide or a metal layer with a specific work function, or made of dielectric material. In this exemplary embodiment, the material layer is made of polysilicon formed through chemical vapor deposition (CVD) process. Then, an etching process such as an anisotropic etching process is performed to remove a part of the material layer until the dielectric layer 76 on the two gate structures 72/74 is exposed, and the remaining material layer may include two spacers 78/80 respectively formed at the opposite sidewall outer sides S3/S4 of the two gate structures 72/74 in the first region 40, and a spacer 82 formed at a side of the second gate layer 58 in the second region 42. In the first region 40, the spacer 78 at the sidewall outer side S3 of the gate structures 72 and the spacer 80 at the sidewall outer side S4 of the gate structures 74 have the same height and the same bottom width; furthermore, the arc surface of the spacer 78 and the arc surface of the spacer 80 have opposite protruding directions. In the second region 42, the spacer 82 made of conductive material is formed at a side of the second gate layer 58, and the spacer shaped protective layer 70″ made of dielectric material at another side of the second gate layer 58. Moreover, an ion implantation process could be further performed, source/drain regions 84/86 are respectively formed in the semiconductor substrate 46 at two sides of the two gate structures 72/74. Accordingly, a semiconductor device 88 is completed in the first region 40.

As illustrated above, in this exemplary embodiment, a flash memory cell is used as an example. Therefore, in each of the gate structures 72/74 of the semiconductor device 88 in the first region 40, the first dielectric layer 52 may serve as a tunneling oxide layer, the first gate layer 54 may serve as a floating gate, the second dielectric layer 56 may serve as an inter-gate oxide layer, i.e. an oxide layer between gates, and the second gate layer 58 may serve as a control gate. Additionally, each of the two spacers 78/80 made of conductive material may serve as a third gate layer, i.e. a select gate. The dielectric layer 76 between the spacer 78 and the gate structures 72 and between the spacer 80 and the gate structures 74 may serve as an inter-gate oxide layer, so that the spacers 78/80, the first gate layer 54 and the second dielectric layer 56 could be electrically insulated from each other.

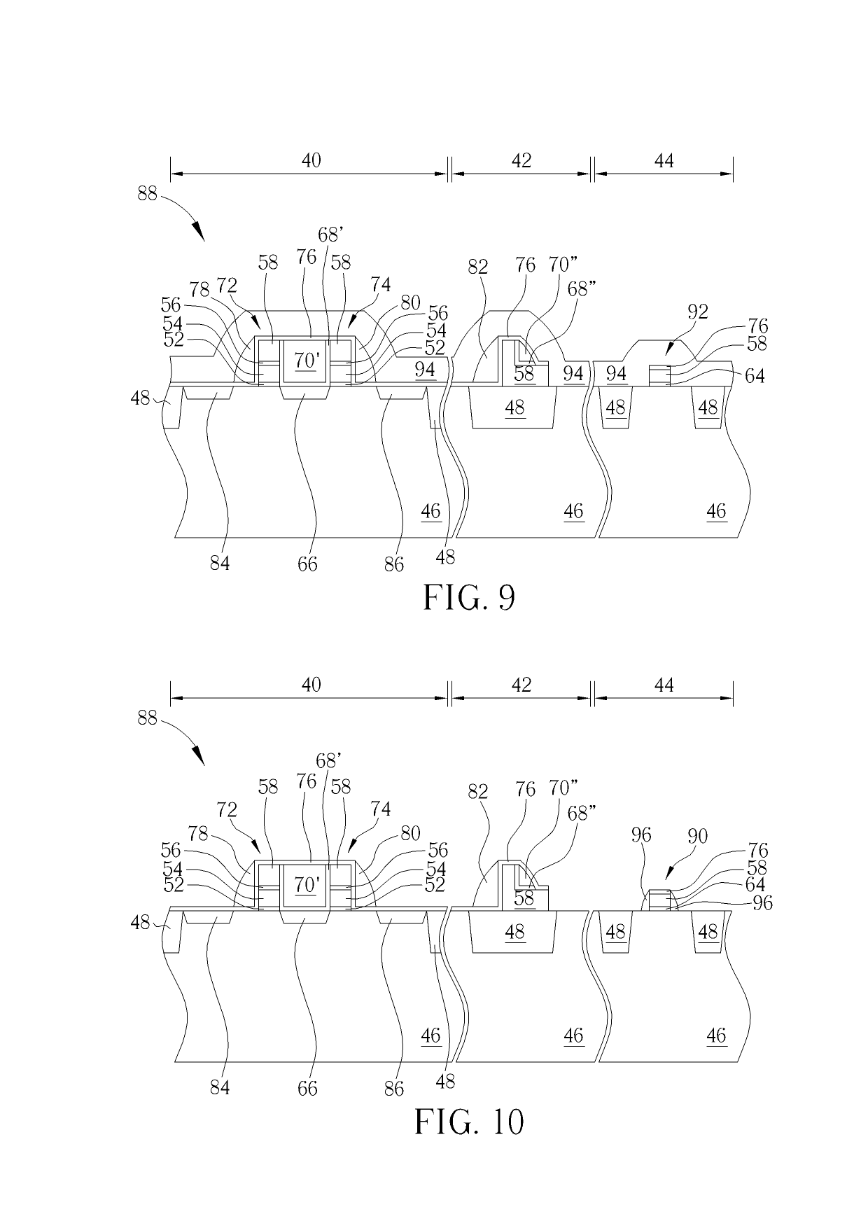

As shown in FIG. 9 and FIG. 10, a semiconductor device 90 is completed in the third region 44 through other known semiconductor processed. For example, a patterned mask (not shown) is formed and used in an etching process, and the etching process is performed to remove a part of the second gate layer 58 in the third region 44 to define a gate structure 92 such as a MOS gate structure in the third region 44. Then, a nitride layer 94 is conformally formed on the semiconductor substrate 46. Subsequently, an etching back process is performed to remove a part of the nitride layer 94, and a spacer 96 made of nitride is formed on the sidewalls of the gate structure 92. It is appreciate that, in the first region, each of the spacers 78/80 is disposed at one side of each of the gate structures 72/74, and the protective layer 70′ is disposed at another side of each of the gate structures 72/74. Furthermore, the protective layer 70′ preferably has a planar top and fills the space between the two gate structures 72/74, but not limited thereto, the protective layer 70′ could have a non-planar top; for example, the top of the protective layer 70′ may include a V-shaped concave. The two sides of each of the gate structures 72/74 in the first region 40 have been protected by the protective layer 70′ and the spacers 78/80, accordingly, the residues caused by the semiconductor processes performed in the third region 44, like the semiconductor process used for forming the nitride spacer 96 for example, can be avoided to be formed on the sidewalls of each of the gate structures 72/74, thereby stabilizing the performances of the semiconductor device 88 in the first region 40.

In conclusion, the present invention provides a semiconductor device having a spacer only disposed at a side of the gate structure and a protective layer disposed at another side of the gate structure, accordingly, the residues caused by other semiconductor processes can be prevented from being formed on the sidewalls of the gate structure. Consequently, the data retention ability of the flash memory cell may be preserved, and the performances of the semiconductor device can be improved.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor device, comprising:
a semiconductor substrate;
at least a first gate structure disposed on the semiconductor substrate;
a spacer only disposed at a side of the first gate structure, wherein a material of the spacer does not comprise nitride;
a protective layer disposed at another side of the first gate structure; and
a dielectric layer disposed between the spacer and the first gate structure simultaneously covering the first gate structure and the protective layer.

2. (canceled)

3. The semiconductor device according to claim 1, wherein the protective layer is made of dielectric material and a material of the protective layer does not comprise nitride.

4. The semiconductor device according to claim 1, wherein a height of the protective layer is substantially the same as a height of the first gate structure.

5. The semiconductor device according to claim 1, further comprising:
a second gate structure disposed on the semiconductor substrate, wherein the protective layer is disposed on the semiconductor substrate between the first gate structure and the second gate structure.

6. The semiconductor device according to claim 5, further comprising:
a communal doped region disposed in the semiconductor substrate underneath the protective layer.

7. The semiconductor device according to claim 6, wherein the protective layer overlaps the communal doped region.

8. The semiconductor device according to claim 1, wherein the spacer is made of dielectric material and the dielectric material does not comprise nitride.

9. The semiconductor device according to claim 1, wherein the spacer is made of conductive material.

10. The semiconductor device according to claim 9, wherein the spacer comprises a select gate.

11. The semiconductor device according to claim 1, wherein the first gate structure comprises a first dielectric layer, a first gate, a second dielectric layer and a second gate disposed sequentially on the semiconductor substrate.

12. The semiconductor device according to claim 11, wherein the first gate comprises a floating gate, and the second gate comprises a control gate.

13. A method of fabricating a semiconductor device, comprising:
forming a gate stack layer on a semiconductor substrate, wherein the gate stack layer comprises at least an opening;
forming a protective layer filling the opening; and
removing a part of the gate stack layer to form two gate structures after forming the protective layer, wherein the protective layer is between the two gate structures.

14. The method of fabricating a semiconductor device according to claim 13, wherein the protective layer is made of dielectric material and a material of the protective layer does not comprise nitride.

15. The method of fabricating a semiconductor device according to claim 13, wherein a height of the protective layer between the two gate structures is substantially the same as a height of each of the two gate structures.

16. The method of fabricating a semiconductor device according to claim 13, before forming the protective layer, further comprising forming a dielectric layer covering surfaces exposed by the opening, wherein the opening is not filled up with the dielectric layer.

17. The method of fabricating a semiconductor device according to claim 13, after forming the protective layer, further comprising:
forming a dielectric layer covering the two gate structures and the protective layer; and
respectively forming two spacers at the opposite sidewall outer sides of the two gate structures.

18. The method of fabricating a semiconductor device according to claim 17, wherein the two spacers are made of dielectric material and the dielectric material does not comprise nitride.

19. The method of fabricating a semiconductor device according to claim 17, wherein the two spacers are made of conductive material.

20. The method of fabricating a semiconductor device according to claim 13, wherein each of the two gate structures comprises a tunneling oxide layer, a floating gate, an inter-gate oxide layer and a control gate.
